(19) United States
(12) Patent Application Publication
(10) Pub. No.: US 2026/0271309 A1
(43) Pub. Date: Sep. 10, 2026

(54) SEMICONDUCTOR MEMORY DEVICE

(71) Applicant: Samsung Electronics Co., Ltd., Suwon-si (KR)

(72) Inventors: Yu Jin Kim, Suwon-si (KR); Jin-Woo Han, Suwon-si (KR); Ju Hyun Kim, Suwon-si (KR); Hyeon Cheol Kim, Suwon-si (KR)

(73) Assignee: Samsung Electronics Co., Ltd., Suwon-si (KR)

(21) Appl. No.: 19/327,997

(22) Filed: Sep. 12, 2025

(30) Foreign Application Priority Data
Mar. 4, 2025 (KR) 10-2025-0027704

(51) Int. Cl. H10B 80/00; H01L 23/00; H01L 25/065; H01L 25/18; H10B 12/00

(52) U.S. Cl. CPC H10B 80/00; H10B 12/30; H10B 12/50; H10W 90/00; H10W 90/792

(57) ABSTRACT

A semiconductor memory device includes a cell structure; and a peripheral circuit structure on the cell structure, wherein the cell structure includes a first substrate, stack structures spaced apart from one another in a first horizontal direction on the substrate, including word lines spaced apart from one another in a vertical direction, each word line having a stepwise shape, word line contacts electrically connected to the word lines, and landing pads electrically connected to the word line contacts, the peripheral circuit structure includes a second substrate, insulating patterns passing through the second substrate, and through vias electrically connected to the landing pads, each of the through vias constitutes via groups including first to fourth through vias adjacent to one another, and the first to fourth through vias of the via groups pass through the insulating patterns, respectively.

### CROSS-REFERENCE TO RELATED APPLICATIONS

This present application claims priority to and the benefit under 35 U.S.C. § 119(a)-(d) of Korean Patent Application No. 10-2025-0027704 filed on Mar. 4, 2025, in the Korean Intellectual Property Office, the entire disclosure of which is herein incorporated by reference.

### FIELD

The present disclosure relates to a semiconductor memory device, and more particularly, to a three-dimensional semiconductor memory device.

### BACKGROUND

It may be needed to increase the degree of integration of a semiconductor device in order to meet excellent performance and low price, which may be needed by consumers. Since the degree of integration of the semiconductor device may be an important factor that determines the price of a product, an increased degree of integration may be particularly needed.

In case of a two-dimensional or planar semiconductor device of the related art, since the degree of integration of the two-dimensional or planar semiconductor device may be mainly determined by an area occupied by a unit memory cell, the two-dimensional or planar semiconductor device may be greatly affected by a level of technology for forming a fine pattern. However, since ultra-high-priced equipment may be needed for pattern miniaturization, the degree of integration of the two-dimensional semiconductor device may be increasing but still limited. Accordingly, three-dimensional semiconductor memory devices with memory cells three-dimensionally arranged have been proposed.

### SUMMARY

An object of the present disclosure is to provide a semiconductor memory device in which product reliability is improved.

According to aspects of the present disclosure, there is provided a semiconductor memory device including a cell structure; and a peripheral circuit structure on the cell structure, wherein: the cell structure includes a first substrate, stack structures spaced apart from one another in a first horizontal direction on the substrate, including word lines spaced apart from one another in a vertical direction, each word line having a stepwise shape, word line contacts electrically connected to the word lines, and landing pads electrically connected to the word line contacts, the peripheral circuit structure includes a second substrate, insulating patterns passing through the second substrate, and through vias electrically connected to the landing pads, each of the through vias constitutes via groups including first to fourth through vias adjacent to one another, and the first to fourth through vias of the via groups pass through the insulating patterns, respectively.

According to the aforementioned and other embodiments of the present disclosure, there is provided a semiconductor memory device including a cell structure; and a peripheral circuit structure on the cell structure, wherein: the cell structure includes a first substrate, stack structures spaced apart from one another in a first horizontal direction on the substrate, including word lines spaced apart from one another in a vertical direction, each word line having a stepwise shape, word line contacts electrically connected to the word lines, and landing pads electrically connected to the word line contacts, the peripheral circuit structure includes a second substrate, insulating patterns passing through the second substrate, through vias electrically connected to the landing pads in the insulating patterns, and peripheral circuit transistors electrically connected to the through vias on the second substrate, and the insulating patterns are spaced apart from one another in the first horizontal direction and a second horizontal direction.

According to the aforementioned and other embodiments of the present disclosure, there is provided a semiconductor memory device including a cell structure and a peripheral circuit structure, which include a bit line connection region and a word line connection region, wherein: the cell structure includes a first substrate, stack structures spaced apart from one another in a first horizontal direction on the first substrate, and word line contacts, each of the stack structures includes a bit line extended from the bit line connection region in a vertical direction, semiconductor patterns connected to the bit line in the bit line connection region, extended in the first horizontal direction and spaced apart from one another in the vertical direction, data storage elements connected to the semiconductor patterns in the bit line connection region, word lines including pad portions extended in a second horizontal direction from the bit line connection region to the word line connection region, crossing the semiconductor patterns in the bit line connection region and having a stepwise shape in the word line connection region, and word line contacts on pad portions, the peripheral circuit structure includes a second substrate, insulating patterns passing through the second substrate in the bit line connection region, through vias passing through the insulating patterns, and peripheral circuit transistors on the second substrate in the bit line connection region, each of the through vias constitutes via groups including first to fourth through vias adjacent to one another, and the first to fourth through vias of each of the via groups pass through the insulating patterns, respectively.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating a semiconductor memory device according to some embodiments;

FIG. 2 is an exemplary layout view illustrating a semiconductor memory device according to some embodiments;

FIG. 3 is an exemplary layout view illustrating a word line connection region of a semiconductor memory device according to some embodiments;

FIG. 4 is a cross-sectional view taken along line A-A′ of FIG. 2;

FIG. 5 is a cross-sectional view taken along line B-B′ of FIG. 2;

FIG. 6 is a cross-sectional view taken along line C-C′ of FIG. 3;

FIG. 7 is a cross-sectional view taken along line D-D′ of FIG. 3;

FIG. 8 is an exemplary layout view illustrating a word line connection region of a semiconductor memory device according to some embodiments;

FIG. 9 is an exemplary layout view illustrating a word line connection region of a semiconductor memory device according to some embodiments;

FIG. 10 is a cross-sectional view taken along line E-E′ of FIG. 9;

FIG. 11 is an exemplary layout view illustrating a word line connection region of a semiconductor memory device according to some embodiments; and

FIGS. 12 and 13 are cross-sectional views illustrating a semiconductor memory device according to some embodiments.

### DETAILED DESCRIPTION

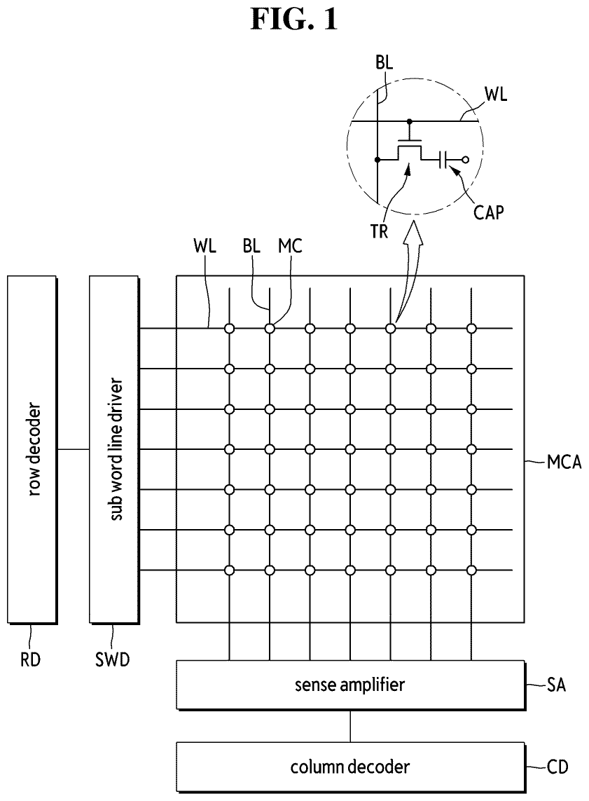

FIG. 1 is a block diagram illustrating a semiconductor memory device according to some embodiments.

Referring to FIG. 1, the semiconductor memory device according to some embodiments may include a memory cell array MCA, a row decoder RD, a sense amplifier SA, and a column decoder CD.

The memory cell array MCA may include a plurality of three-dimensionally arranged memory cells MC. The memory cells MC may be connected between word lines WL and bit lines BL, which cross one another. The memory cell MC may be, for example, DRAM.

The memory cell MC may include a cell transistor TR and a data storage element CAP. For example, the data storage element CAP may be a capacitor. The cell transistor TR and the data storage element CAP may be electrically connected to one another in series. A gate of the cell transistor TR may be connected to the word line WL, a source of the cell transistor TR may be connected to the bit line BL, and a drain of the cell transistor TR may be connected to the data storage element CAP.

The row decoder RD may decode an address input from the outside to select one of the word lines WL of the memory cell array MCA. The address decoded in the row decoder RD may be provided to a sub word line driver SWD.

The sub word line driver SWD may provide a predetermined voltage to each of the selected word line WL and unselected word lines WL in response to control of control circuits.

The sense amplifier SA may detect and amplify a voltage difference between a bit line BL selected in accordance with an address decoded from the column decoder CD and a reference bit line and output the voltage difference.

The column decoder CD may provide a data transmission path between the sense amplifier SA and an external device (e.g., a memory controller). The column decoder CD may decode the address input from the outside to select one of the bit lines BL.

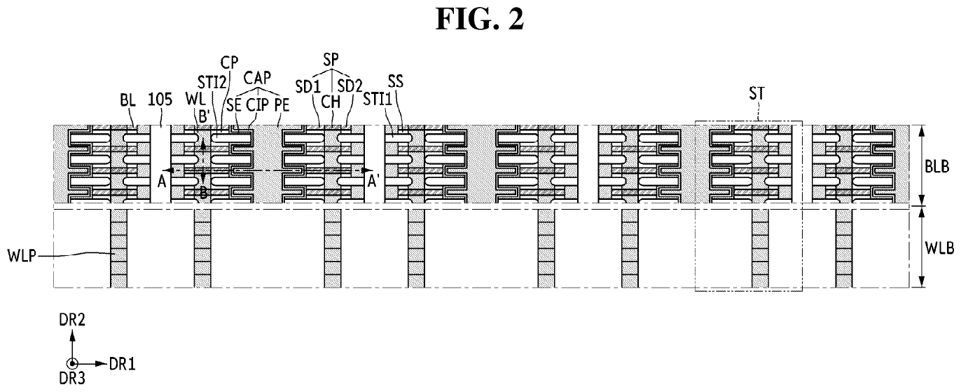

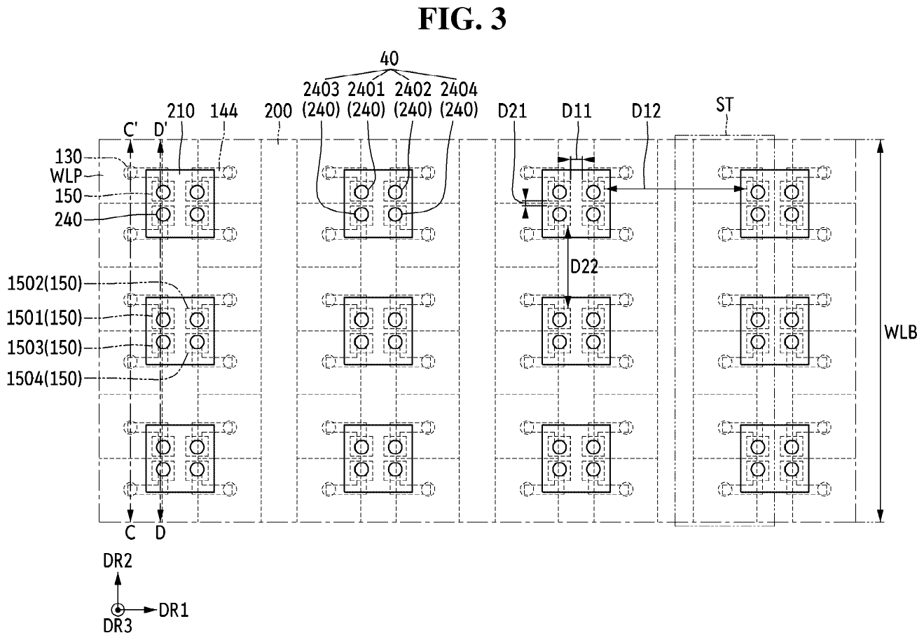

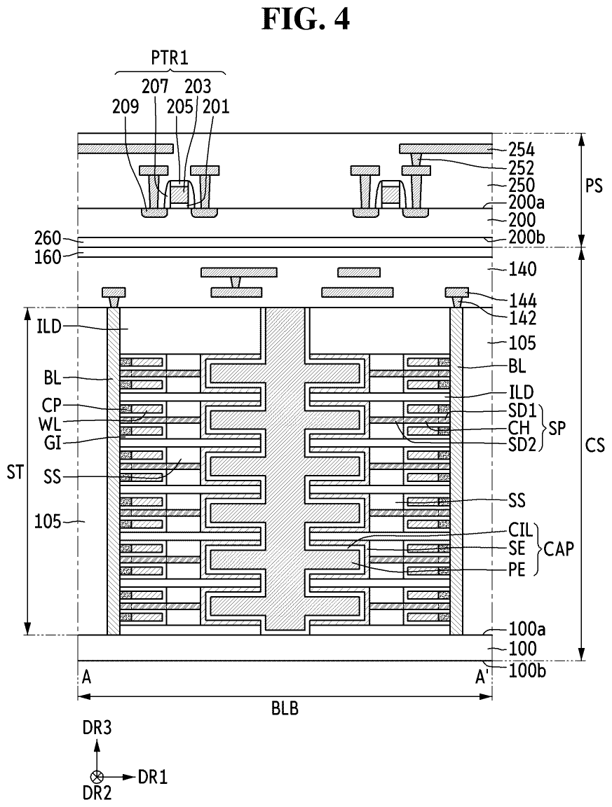

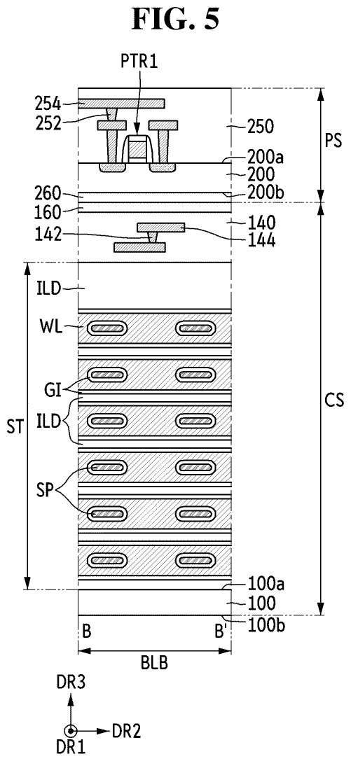

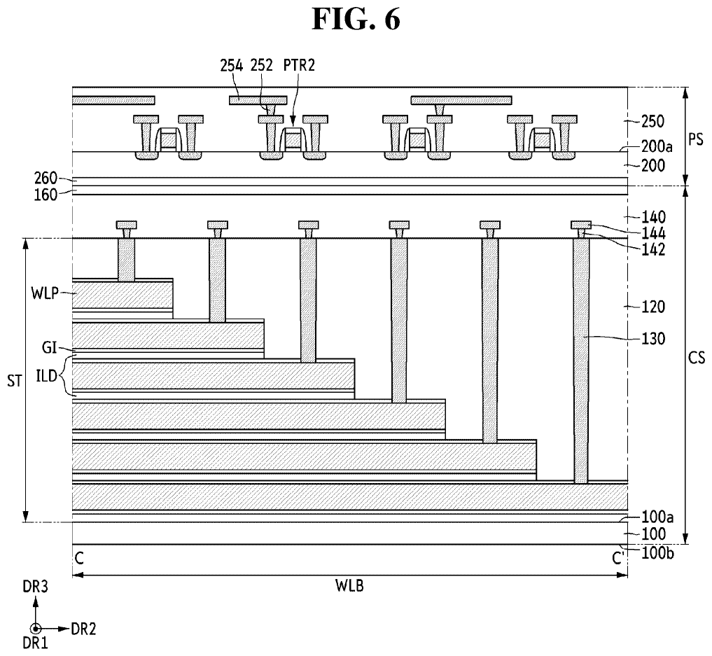

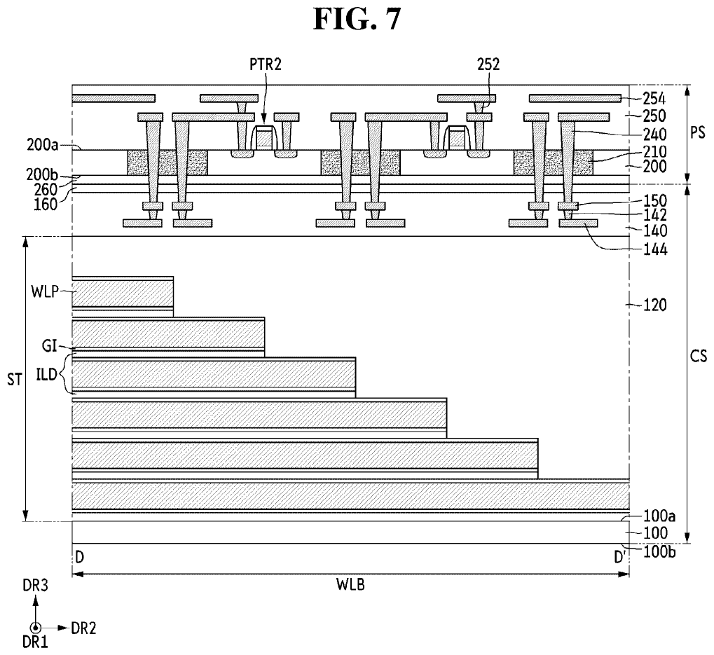

FIG. 2 is an exemplary layout view illustrating a semiconductor memory device according to some embodiments. FIG. 3 is an exemplary layout view illustrating a word line connection region of a semiconductor memory device according to some embodiments. FIG. 4 is a cross-sectional view taken along line A-A′ of FIG. 2. FIG. 5 is a cross-sectional view taken along line B-B′ of FIG. 2. FIG. 6 is a cross-sectional view taken along line C-C′ of FIG. 3. FIG. 7 is a cross-sectional view taken along line D-D′ of FIG. 3.

Referring to FIGS. 2 to 7, the semiconductor memory device according to some embodiments includes a cell structure CS and a peripheral circuit structure PS. Each of the cell structure CS and the peripheral circuit structure PS may include a bit line connection region BLB and a word line connection region WLB.

The cell structure CS may include a first substrate 100, a plurality of stack structures ST on the first substrate 100, a cell insulating layer 120, word line contacts 130, a first insulating layer 140, first vias 142, first wirings 144, landing pads 150, and a first bonding insulating layer 160. The memory cells MC of FIG. 1 may be formed on a first surface 100a of the first substrate 100. The memory cells MC may be arranged on the first surface 100a of the first substrate 100 in a first horizontal direction DR1, a second horizontal direction DR2, and a vertical direction DR3.

The first horizontal direction DR1, the second horizontal direction DR2, and the vertical direction DR3 may cross one another. The first horizontal direction DR1 and the second horizontal direction DR2 may be parallel with the first surface 100a of the first substrate 100. The vertical direction DR3 may be perpendicular to the first surface 100a of the first substrate 100. Hereinafter, a lower portion, an upper portion, a lower surface, and an upper surface are defined based on the vertical direction DR3.

The first substrate 100 may include a first surface 100a and a second surface 100b, which are opposite to one another. The first substrate 100 may be a bulk silicon or a silicon-on-insulator (SOI). The first substrate 100 may be a silicon substrate, or may include another material, for example, silicon germanium, gallium arsenide, silicon germanium on insulator (SGOI), indium antimony, lead tellurite compound, indium arsenide, indium phosphide, gallium arsenide or gallium antimony. Alternatively, the first substrate 100 may be a substrate having an epitaxial layer formed on a base substrate, or may be a ceramic substrate, a quartz substrate, or a glass substrate for a display.

The stack structure ST may be arranged on the first surface 100a of the first substrate 100. The stack structure ST may include interlayer insulating patterns ILD, semiconductor patterns SP, bit lines BL, word lines WL, a gate insulating film GI, a capping insulating pattern CP, a spacer insulating pattern SS, first and second isolation insulating patterns STI1 and STI2, and a data storage element CAP.

The interlayer insulating patterns ILD may be stacked on the first surface 100a of the first substrate 100 in the vertical direction DR3. The interlayer insulating pattern ILD may include an insulating material. For example, the interlayer insulating pattern ILD may include at least one of a silicon oxide film, a silicon nitride film, a silicon oxynitride film, a carbon-containing silicon oxide film, a carbon-containing silicon nitride film, or a carbon-containing silicon oxynitride film. For example, the interlayer insulating pattern ILD may include a silicon oxide film.

The semiconductor patterns SP may be arranged in the bit line connection region BLB. The semiconductor patterns SP may be spaced apart from one another in the vertical direction DR3. The semiconductor pattern SP may be arranged between the interlayer insulating patterns ILD adjacent to one another in the vertical direction DR3. The interlayer insulating pattern ILD may be arranged between the semiconductor patterns SP adjacent to one another in the vertical direction DR3.

The semiconductor pattern SP may extend long in the first horizontal direction DR1. The semiconductor patterns SP positioned at the same height may be spaced apart from one another in the second horizontal direction DR2. In the cross-sectional view as shown in FIG. 4, the interlayer insulating pattern ILD may be more protruded in the first horizontal direction DR1 than the semiconductor pattern SP.

The semiconductor pattern SP may include at least one of a single crystal semiconductor, a polycrystalline semiconductor, an oxide semiconductor, or a two-dimensional material. For example, the single crystal semiconductor may be a single crystal silicon. For example, the oxide semiconductor may be a polysilicon. For example, the oxide semiconductor may be selected from IGZO(InGaZnO), Sn-IGZO, IWO(InWO), IZO(InZnO), ZTO(ZnSnO), ZnO, YZO(yttrium-doped zinc oxide), IGSO(InGaSiO), InO, SnO, TiO, ZnON, MgZnO, ZrInZnO, HfInZnO, SnInZnO, AlSnInZnO, SiInZnO, AlZnSnO, GaZnSnO, and ZrZnSnO, but is not limited thereto. For example, the two-dimensional semiconductor may be made of a transition metal dichalcogenide, or a bipolar semiconductor material that utilizes both electrons and holes as driving charges. For example, the two-dimensional semiconductor material may be selected from MoS₂, MoSe₂, WS₂, NbS₂, TaS₂, ZrS₂, HfS₂, TcS₂, ReS₂, CuS₂, GaS₂, InS₂, SnS₂, GeS₂, PbS₂, WSe₂, NbSe₂, TaSe₂, ZrSe₂, HfSe₂, TcSe₂, ReSe₂, CuSe₂, GaSe₂, InSe₂, SnSe₂, GeSe₂, PbSe₂, MoTe₂, WTe₂, NbTe₂, TaTe₂, ZrTe₂, HfTe₂, TcTe₂, ReTe₂, CuTe₂, GaTe₂, InTe₂, SnTe₂, GeTe₂, and PbTe₂, but is not limited thereto.

The semiconductor pattern SP may include a channel region CH, a first impurity region SD1, and a second impurity region SD2. The channel region CH may be interposed between the first and second impurity regions SD1 and SD2. The first impurity region SD1 may be connected to the bit line BL. The second impurity region SD2 may be connected to the data storage element CAP. The second impurity region SD2 may be connected to a storage electrode SE.

The channel region CH may correspond to a channel of the cell transistor TR described with reference to FIG. 1. The first and second impurity regions SD1 and SD2 may correspond to source and drain of the cell transistor TR described with reference to FIG. 1, respectively.

The first and second impurity regions SD1 and SD2 may be regions doped with impurities in the semiconductor pattern SP. The first and second impurity regions SD1 and SD2 may have an n-type or a p-type conductivity. The first impurity region SD1 may be formed at a first end of the semiconductor pattern SP, and the second impurity region SD2 may be formed at a second end of the semiconductor pattern SP. The second end may be opposite to the first end in the first horizontal direction DR1.

The bit lines BL may be arranged in the bit line connection region BLB. The bit line BL may extend long in the vertical direction DR3. The bit lines BL may be spaced apart from one another in the second horizontal direction DR2. The bit lines BL may be arranged on the semiconductor patterns SP and the interlayer insulating patterns ILD. The bit line BL may be connected to the semiconductor patterns SP spaced apart from one another in the vertical direction DR3.

The bit line BL may include a conductive material, for example, at least one of a doped semiconductor material (doped silicon, doped silicon-germanium, doped germanium, etc.), a conductive metal nitride (titanium nitride, tantalum nitride, etc.), metal (tungsten, titanium, tantalum, etc.), and a metal-semiconductor compound (tungsten silicide, cobalt silicide, titanium silicide, etc.), but is not limited thereto.

The word line WL may be arranged on at least a portion of an outer peripheral surface of the channel region CH of the semiconductor pattern SP. The word lines WL may extend long in the second horizontal direction DR2. The word lines WL may be spaced apart from one another in the vertical direction DR3. The word lines WL may cross the semiconductor patterns SP, which are spaced apart from one another in the second horizontal direction DR2 at the same height.

In some embodiments, the cell transistor TR of FIG. 1 may be a gate-all-around transistor. The word line WL may surround the channel region CH. The word line WL may surround the outer peripheral surface of the channel region CH. The word line WL may extend in the second horizontal direction DR2 to surround the channel region CH of the respective semiconductor patterns SP arranged to be spaced apart from one another in the second horizontal direction DR2 at the same height.

Unlike the shown example, in some other embodiments, the cell transistor TR of FIG. 1 may have a double gate transistor structure. The word lines WL may be arranged on opposite sidewalls (e.g., sidewalls opposite to one another in the vertical direction DR3) of the channel region CH and spaced apart from one another. In some other embodiments, the word line WL may be arranged on one sidewall of the channel region CH.

The word lines WL and the interlayer insulating patterns ILD may extend from the bit line connection region BLB to the word line connection region WLB. The word lines WL and the interlayer insulating patterns ILD may have a stepwise structure in the word line connection region WLB. For example, in the word line connection region WLB, lengths of the word lines WL in the second horizontal direction DR2 may increase as the word lines WL approach the first substrate 100. The word lines WL may include a pad portion WLP having a stepwise structure in the word line connection region WLB. An upper surface of the pad portion WLP may be exposed. A portion of the word line WL of which upper surface is exposed by another word line WL arranged thereon may be referred to as the pad portion WLP.

The word line WL may include a conductive material. For example, the word line WL may include at least one of a doped semiconductor material, a conductive metal nitride, metal, or a metal-semiconductor compound, but is not limited thereto.

The gate insulating film GI may be arranged between the word line WL and the semiconductor pattern SP, and between the word line WL and the interlayer insulating pattern ILD. The gate insulating film GI may extend along upper and lower surfaces of the word line WL and one sidewall extended in the vertical direction DR3 and adjacent to the spacer insulating pattern SS.

The gate insulating film GI may include at least one of, for example, a high dielectric constant insulating film, a silicon oxide film, a silicon nitride film or a silicon oxynitride film.

The capping insulating pattern CP may be arranged between the first impurity region SD1 of the semiconductor pattern SP and the interlayer insulating pattern ILD. The capping insulating pattern CP may be arranged on upper and lower surfaces of the semiconductor pattern SP. The capping insulating pattern CP may spatially separate the bit line BL from the word line WL. The gate insulating film GI may be interposed between the capping insulating pattern CP and the interlayer insulating pattern ILD, and between the capping insulating pattern CP and the semiconductor pattern SP.

The spacer insulating pattern SS may be arranged between the second impurity region SD2 of the semiconductor pattern SP and the interlayer insulating pattern ILD. The spacer insulating pattern SS may be arranged on the upper and lower surfaces of the semiconductor pattern SP. The spacer insulating pattern SS may be spaced apart from the word line WL with the gate insulating film GI interposed therebetween. The gate insulating film GI may be interposed between the spacer insulating pattern SS and the interlayer insulating pattern ILD, and between the spacer insulating pattern SS and the semiconductor pattern SP.

Each of the capping insulating pattern CP and the spacer insulating pattern SS may include at least one of, for example, a silicon oxide film, a silicon nitride film, a silicon oxynitride film, a carbon-containing silicon oxide film, a carbon-containing silicon nitride film, or a carbon-containing silicon oxynitride film.

The first and second isolation insulating patterns STI1 and STI2 may be arranged on the first surface 100a of the first substrate 100. The first isolation insulating pattern STI1 may be arranged between the bit lines BL adjacent to one another in the second horizontal direction DR2. The second isolation insulating pattern STI2 may be arranged between the storage electrodes SE adjacent to one another in the second horizontal direction DR2.

A buried insulating pattern 105 may be arranged on the first surface 100a of the first substrate 100. The buried insulating pattern 105 may cover a sidewall of the bit line BL and a sidewall of the first isolation insulating pattern STI1.

Each of the first and second isolation insulating patterns STI1 and STI2 and the buried insulating pattern 105 may be formed of at least one of insulating materials formed using spin on glass (SOG) technology, silicon oxide, or silicon oxynitride.

The data storage element CAP may be arranged in the bit line connection region BLB. The data storage element CAP may be arranged on the plurality of semiconductor patterns SP and the interlayer insulating pattern ILD. The data storage element CAP may include a capacitor dielectric layer CIL, a plurality of storage electrodes SE and a plate electrode PE. Each data storage element CAP may include a storage electrode SE, a capacitor dielectric layer CIL, and a plate electrode PE, which are arranged between the interlayer insulating patterns ILD. Each data storage element CAP may be defined by each storage electrode SE.

The capacitor dielectric layer CIL may be arranged on the storage electrode SE and the interlayer insulating pattern ILD. The capacitor dielectric layer CIL may extend along profiles of the plurality of storage electrodes SE and sides of the plurality of interlayer insulating patterns ILD. The plate electrode PE may be arranged on the capacitor dielectric layer CIL. The capacitor dielectric layer CIL and the plate electrode PE may be sequentially arranged on the storage electrode SE.

The capacitor dielectric layer CIL and the plate electrode PE, which are included in each data storage element CAP, may be connected to one another.

Each of the storage electrode SE and the plate electrode PE may include, for example, a doped semiconductor material, a conductive metal nitride (e.g., titanium nitride, tantalum nitride, niobium nitride, or tungsten nitride), metal (e.g., ruthenium, iridium, titanium, niobium, tungsten, cobalt, molybdenum, or tantalum), and a conductive metal oxide (e.g., iridium oxide or niobium oxide), but is not limited thereto. For example, the storage electrode SE may include a conductive metal nitride, metal, and a conductive metal oxide. The conductive metal nitride, the metal, and the conductive metal oxide may be included in a metallic conductive layer.

The capacitor dielectric layer CIL may include, for example, a high dielectric constant material (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or their combination). In the semiconductor memory device according to some embodiments, the capacitor dielectric layer CIL may include a stacked layer structure in which zirconium oxide, aluminum oxide, and zirconium oxide are sequentially stacked. In the semiconductor memory device according to some embodiments, the capacitor dielectric layer CIL may include hafnium (Hf).

The stack structure ST may be arranged in the first horizontal direction DR1. The stack structures ST adjacent to one another in the first horizontal direction DR1 may share the data storage element CAP or the buried insulating pattern 105. The stack structures ST that are adjacent to one another in the first horizontal direction DR1 and share the data storage element CAP may be symmetric in the first horizontal direction DR1 based on the plate electrode PE of the data storage element CAP. The stack structures ST that are adjacent to one another in the first horizontal direction DR1 and share the buried insulating pattern 105 may be symmetric in the first horizontal direction DR1 based on the buried insulating pattern 105.

The cell insulating layer 120 may be arranged in the word line connection region WLB. The cell insulating layer 120 may cover the stepwise structure of the word lines WL and the interlayer insulating pattern ILD. The cell insulating layer 120 may cover the pad portion WLP. An upper surface of the cell insulating layer 120 may be located at substantially the same level as an uppermost surface of the interlayer insulating patterns ILD. The cell insulating layer 120 may include an insulating material, and may include a plurality of layers.

The word line contacts 130 may be arranged in the word line connection region WLB. The word line contacts 130 may be arranged on the word lines WL. The word line contacts 130 may be arranged on the word lines WL of each stack structure ST. The word line contacts 130 may be electrically connected to the word lines WL of each stack structure ST.

The word line contacts 130 may be arranged in the cell insulating layer 120. The word line contacts 130 may extend in the vertical direction DR3. The word line contacts 130 may pass through the cell insulating layer 120. Each of the word line contacts 130 may be in contact with each of the word lines WL of each stack structure ST.

The first insulating layer 140 may be arranged on the stack structure ST and the cell insulating layer 120. The first insulating layer 140 may include an insulating material, and may include a plurality of layers.

The first vias 142 and the first wirings 144 may be arranged in the cell insulating layer 120. Each of the first vias 142 and the first wirings 144 may include a conductive material. Various modifications may be made in the number, arrangement, and connection relation of the first vias 142 and the first wirings 144.

The landing pads 150 may be arranged in the word line connection region WLB. The landing pads 150 may be arranged in the cell insulating layer 120. In some embodiments, the landing pads 150 may be arranged in the uppermost metal layer in the cell insulating layer 120 as one of the first wirings 144.

Each of the landing pads 150 may be arranged on each of the word line contacts 130 on each stack structure ST. Each of the landing pads 150 may be electrically connected to each of the word line contacts 130 on each stack structure ST through the first vias 142 and the first wirings 144.

The first bonding insulating layer 160 may be arranged on the first insulating layer 140. The first bonding insulating layer 160 may be on an uppermost layer of the cell structure CS.

The peripheral circuit structure PS is arranged on the cell structure CS. The peripheral circuit structure PS may include a second substrate 200, insulating patterns 210, first and second peripheral circuit transistors PTR1 and PTR2, a second insulating layer 250, second vias 252, second wirings 254, through vias 240, and second bonding insulating layer.

The second substrate 200 may include a third surface 200a and a fourth surface 200b, which are opposite to one another. The fourth surface 200b of the second substrate 200 may be opposite to the first surface 100a of the first substrate 100.

The second substrate 200 may be a bulk silicon or a silicon-on-insulator (SOI). The second substrate 200 may be a silicon substrate, or may include another material, for example, silicon germanium, gallium arsenide, silicon germanium on insulator (SGOI), indium antimony, lead tellurite compound, indium arsenide, indium phosphide, gallium arsenide or gallium antimony. Alternatively, the second substrate 200 may be a substrate having an epitaxial layer formed on a base substrate, or may be a ceramic substrate, a quartz substrate, or a glass substrate for a display.

The insulating patterns 210 are arranged in the word line connection region WLB. The insulating patterns 210 may be formed in the second substrate 200. The insulating patterns 210 may form an insulating region in the second substrate 200. The insulating patterns 210 may pass through the second substrate 200. The insulating pattern 210 may include an insulating material, for example, at least one of a silicon oxide film, a silicon nitride film, a silicon oxynitride film, a carbon-containing silicon oxide film, a carbon-containing silicon nitride film, or a carbon-containing silicon oxynitride film.

The first and second peripheral circuit transistors PTR1 and PTR2 may be arranged on the third surface 200a of the second substrate 200. The first peripheral circuit transistors PTR1 may be arranged in the bit line connection region BLB, and the second peripheral circuit transistors PTR2 may be arranged in the word line connection region WLB. The first peripheral circuit transistors PTR1 may constitute the sense amplifier SA of FIG. 1, and the second peripheral circuit transistors PTR2 may constitute the sub word line driver SWD of FIG. 1.

Each of the first and second peripheral circuit transistors PTR1 and PTR2 may include a gate insulating pattern 201, a gate electrode 203, a gate capping pattern 205, a gate spacer 207, and source/drain regions 209. The gate insulating pattern 201 may be arranged between the gate electrode 203 and the second substrate 200. The gate capping pattern 205 may be arranged on the gate electrode 203. The gate spacer 207 may cover sidewalls of the gate insulating pattern 201, the gate electrode 203 and the gate capping pattern 205. The source/drain regions 209 may be provided in the second substrate 200 adjacent to both sides of the gate electrode 203.

The second insulating layer 250 may be arranged on the third surface 200a of the second substrate 200. The second insulating layer 250 may include an insulating material and may include a plurality of layers.

The second vias 252 and the second wirings 254 may be arranged in the second insulating layer 250. The first and second peripheral circuit transistors PTR1 and PTR2 may be electrically connected to the second vias 252 and the second wirings 254. The first and second peripheral circuit transistors PTR1 and PTR2 may be electrically connected to the cell structure CS through the second vias 252 and the second wirings 254. The second vias 252 and the second wirings 254 may be electrically connected to the first vias 142 and the first wirings 144.

Each of the second vias 252 and the second wirings 254 may include a conductive material. Various modifications may be made in the number, arrangement, connection relation of the second vias 252 and the second wirings 254.

The second bonding insulating layer 260 may be arranged on the fourth surface 200b of the second substrate 200. The first bonding insulating layer 160 may be in contact with the second bonding insulating layer 260. The first bonding insulating layer 160 and the second bonding insulating layer 260 may be bonded to one another. Each of the first bonding insulating layer 160 and the second bonding insulating layer 260 may include an insulating material such as silicon oxide.

The through vias 240 may be arranged in the word line connection region WLB. The through vias 240 may be arranged in the second insulating layer 250, the insulating pattern 210, the second bonding insulating layer 260, and the first bonding insulating layer 160. The through vias 240 may be electrically connected to the second vias 252 and the second wirings 254.

The through vias 240 may be arranged on the landing pads 150. Each of the through vias 240 may be arranged on each of the landing pads 150. Each of the through vias 240 may be electrically connected to each of the landing pads 150. The through vias 240 may extend in the vertical direction DR3. The through vias 240 may pass through a portion of the second insulating layer 250, the insulating pattern 210, the second bonding insulating layer 260, the first bonding insulating layer 160, and a portion of the first insulating layer 140. Each of the through vias 240 may be in contact with each landing pad 150.

A portion of each landing pad 150 may overlap the pad portion WLP of the word line WL, which is electrically connected to each landing pad 150, in the vertical direction DR3, and the other portion of each landing pad 150 may not overlap the pad portion WLP of the word line WL, which is electrically connected to each landing pad 150, in the vertical direction DR3.

A portion of each through via 240 may overlap the pad portion WLP of the word line WL, which is electrically connected to each through via 240, in the vertical direction DR3, and the other portion of each through via 240 may not overlap the pad portion WLP of the word line WL, which is electrically connected to each through via 240, in the vertical direction DR3.

The second peripheral circuit transistors PTR2 may be electrically connected to the pad portion WLP of the word line WL through second vias 252 and second wirings 254, through vias 240, landing pads 150, first vias 142 and first wirings 144, and word line contacts 130.

For example, the first peripheral circuit transistors PTR1 may be electrically connected to the bit line BL through the second vias 252 and the second wirings 254, through vias passing through the insulating pattern 210 of the bit line connection region BLB, and bit line contacts on the bit line BL. As another example, the first peripheral circuit transistors PTR1 may be electrically connected to the bit line BL through the second vias 252 and the second wirings 254, through vias passing through the second substrate 200 of the bit line connection region BLB, and through bit line contacts on the bit line connection region BLB, and an insulating pattern may be formed on a sidewall of the through via passing through the second substrate 200 of the bit line connection region BLB.

In some embodiments, each through via 240 may be in contact with each landing pad 150. For example, the through via 240 may be in contact with an upper surface of the landing pad 150.

The through vias 240 may constitute via groups 40. Each of the via groups 40 may include through vias spaced apart from one another by N*M (where N and M are natural numbers greater than or equal to two) among the through vias 240. Each of the via groups 40 may include through vias adjacent to one another among the through vias 240. Each of the via groups 40 may pass through each of the insulating patterns 210. That is, the plurality of through vias 240 of one via group 40 may pass through one insulating pattern 210. The insulating pattern 210 may be formed for each of the via groups 40.

In some embodiments, each of the via groups 40 may include through vias spaced apart from one another by N*N among the through vias 240. For example, the via group 40 may include first to fourth through vias 2401 to 2404 spaced apart from one another by 2*2. The first to fourth through vias 2401 to 2404 may pass through one insulating pattern 210.

The first to fourth through vias 2401 to 2404 may be adjacent to one another. The first through via 2401 may be adjacent to the third through via 2403 in the second horizontal direction DR2. The second through via 2402 may be adjacent to the first through via 2401 in the first horizontal direction DR1, and may be adjacent to the fourth through via 2404 in the second horizontal direction DR2. The fourth through via 2404 may be adjacent to the third through via 2403 in the first horizontal direction DR1. The first to fourth through vias 2401 to 2402 constituting the via group 40 may be formed adjacent to one another.

The landing pads 150 may include a first landing pad 1501 electrically connected to the first through via 241, a second landing pad 1502 electrically connected to the second through via 242, a third landing pad 1503 electrically connected to the third through via 243, and a fourth landing pad 1504 electrically connected to the fourth through via 244. The first to fourth landing pads 1501 to 1504 may be formed adjacent to one another. Each insulating pattern 210 may overlap the first to fourth landing pads 1501 to 1504 in the vertical direction DR3. In some embodiments, each of the first to fourth through vias 2401 to 2404 may be in contact with each of the first to fourth landing pads 1501 to 1504.

The via groups 40 may include a first via group and a second via group adjacent to the first via group in the first horizontal direction DR1. A distance D11 between the first landing pad 1501 of the first via group and the second landing pad 1502 of the first via group may be less than a distance D12 between the second landing pad 1502 of the first via group and the first landing pad 1501 of the second via group. A distance between the first through via 2401 of the first via group and the second through via 2402 of the first via group may be less than a distance between the second through via 2402 of the first via group and the first through via 2401 of the second via group.

The via groups 40 may include a first via group and a second via group. The second via group may be adjacent to the first via group in the second horizontal direction DR2. A distance D21 between the first landing pad 1501 of the second via group and the third landing pad 1503 of the second via group may be less than a distance D22 between the third landing pad 1503 of the second via group and the first landing pad 1501 of the first via group. A distance between the first through via 2401 of the second via group and the third through via 2403 of the second via group may be less than a distance between the third through via 2403 of the second via group and the first through via 2401 of the first via group.

In view of a plan view including the first horizontal direction DR1 and the second horizontal direction DR2, the insulating pattern 210 may have a rectangular shape or a square shape.

In some embodiments, the insulating patterns 210 may be spaced apart from one another in the first horizontal direction DR1 and the second horizontal direction DR2. The insulating patterns 210 may be arranged in the first horizontal direction DR1 and the second horizontal direction DR2.

The second peripheral circuit transistors PTR2 constituting the sub word line driver SWD of FIG. 1 may be formed on the second substrate 200 of the word line connection region WLB. Therefore, an area of the insulating patterns 210 should be reduced, so that an area (an area of the second substrate 200 in the word line connection region WLB) in which the second peripheral circuit transistors PTR2 are formed may be increased.

In the semiconductor memory device according to some embodiments, the insulating patterns 210 are spaced apart from one another in the first horizontal direction DR1 and/or the second horizontal direction DR2. Therefore, as compared with the case that the insulating pattern 210 extends long in the first horizontal direction DR1 or the second horizontal direction DR2, the area of the second substrate 200 in the word line connection region WLB may be increased, and the area in which the second peripheral circuit transistors PTR2 are formed may be increased.

Also, in the semiconductor memory device according to some embodiments, the through vias 240 forming the via group 40 are formed adjacent to one another, and a single insulating pattern 210 may insulate the via group 40 from the second substrate 200. Therefore, since the area of the insulating pattern 210 may be further reduced, the area in which the second peripheral circuit transistors PTR2 are formed may be increased. As a result, performance of the second peripheral circuit transistors PTR2 may be improved.

Also, in the semiconductor memory device according to some embodiments, after the insulating patterns 210 in the second substrate 200 are formed, the through vias 240 passing through the insulating patterns 210 may be formed. Since the through vias 240 spaced apart from one another by N*N are formed in one insulating pattern 210, alignment of the through vias 240 may be facilitated.

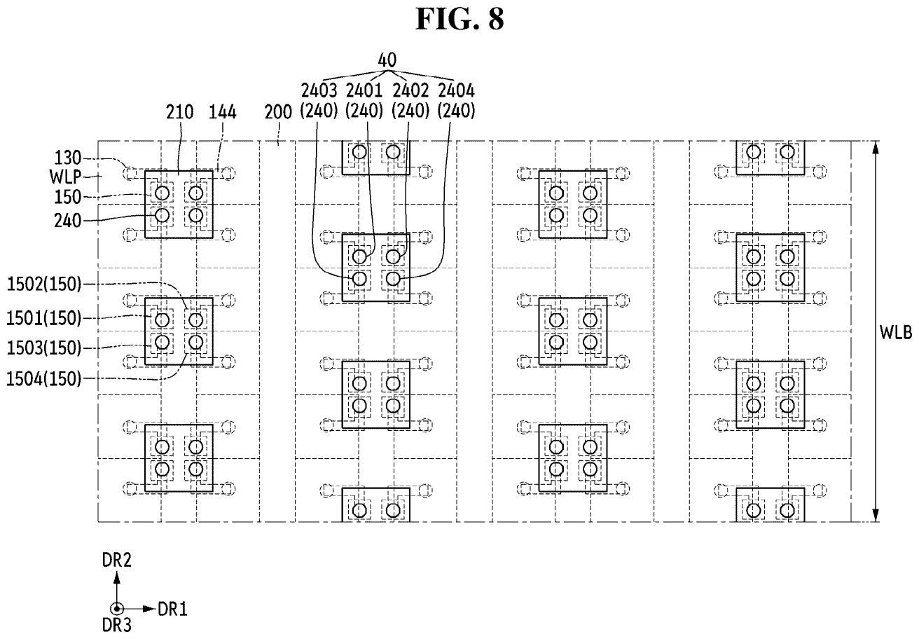

FIG. 8 is an exemplary layout view illustrating a word line connection region of a semiconductor memory device according to some embodiments. For convenience of description, redundant portions of those described with reference to FIGS. 1 to 7 will be briefly described or omitted.

Referring to FIG. 8, in the semiconductor memory device according to some embodiments, the insulating patterns 210 may be arranged in zigzags along the second horizontal direction DR2.

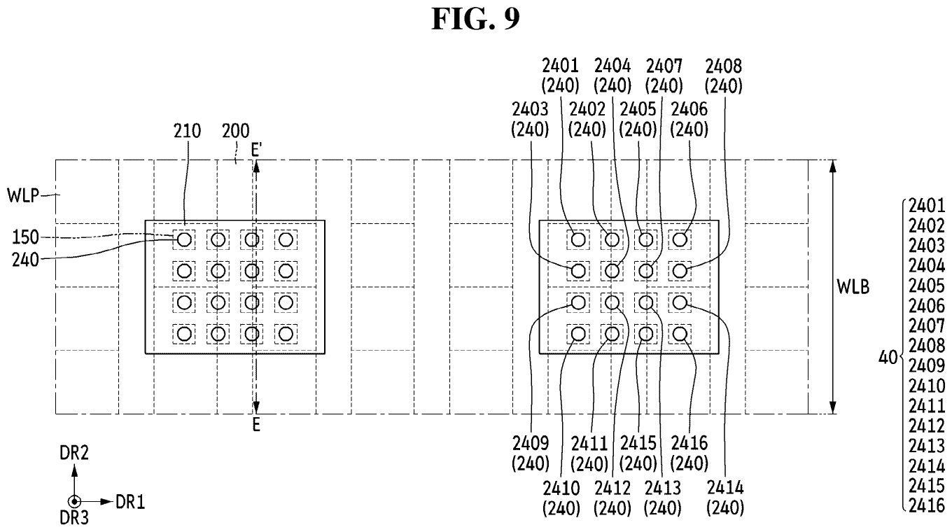

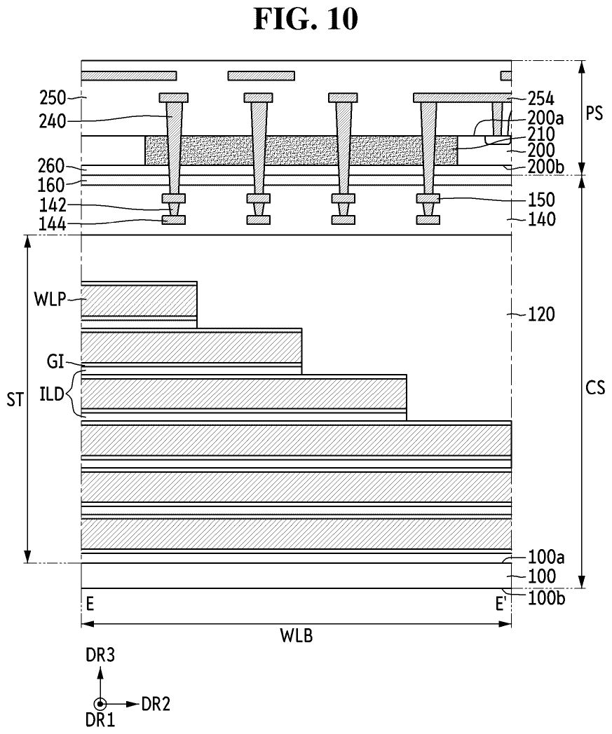

FIG. 9 is an exemplary layout view illustrating a word line connection region of a semiconductor memory device according to some embodiments. FIG. 10 is a cross-18 sectional view taken along line E-E′ of FIG. 9. For convenience of description, redundant portions of those described with reference to FIGS. 1 to 7 will be briefly described or omitted.

Referring to FIGS. 9 and 10, in the semiconductor memory device according to some embodiments, each via group 40 may include first to sixteenth through vias 2401 to 2416 spaced apart from one another by 4*4. The first to sixteenth through vias 2401 to 2416 may pass through one insulating pattern 210. The first to sixteenth through vias 2401 to 2416 may be adjacent to one another.

The fifth to eighth through vias 2405 to 2408 may be adjacent to one another. The fifth through via 2405 may be adjacent to the seventh through via 2407 in the second horizontal direction DR2. The sixth through via 2406 may be adjacent to the fifth through via 2405 in the first horizontal direction DR1, and may be adjacent to the eighth through via 2408 in the second horizontal direction DR2. The eighth through via 2408 may be adjacent to the seventh through via 2407 in the first horizontal direction DR1. The ninth to twelfth through vias 2409 to 2412 may be adjacent to one another. The ninth through via 2409 may be adjacent to the eleventh through via 2411 in the second horizontal direction DR2. The tenth through via 2410 may be adjacent to the ninth through via 2409 in the first horizontal direction DR1, and may be adjacent to the twelfth through via 2412 in the second horizontal direction DR2. The twelfth through via 2412 may be adjacent to the eleventh through via 2411 in the first horizontal direction DR1. The thirteenth to sixteenth through vias 2413 to 2416 may be adjacent to one another. The thirteenth through via 2413 may be adjacent to the fifteenth through via 2415 in the second horizontal direction DR2. The fourteenth through via 2414 may be adjacent to the thirteenth through via 2413 in the first horizontal direction DR1, and may be adjacent to the sixteenth through via 2416 in the second horizontal direction DR2. The sixteenth through via 2416 may be adjacent to the fifteenth through via 2415 in the first horizontal direction DR1. The first to fourth through vias 2401 to 2404 may be adjacent to the ninth to twelfth through vias 2409 to 2412 in the second horizontal direction DR2. The fifth to eighth through vias 2405 to 2408 may be adjacent to the first to fourth through vias 2401 to 2404 in the first horizontal direction DR1, and may be adjacent to the thirteenth to sixteenth through vias 2413 to 2416 in the second horizontal direction DR2. The thirteenth to sixteenth through vias 2413 to 2416 may be adjacent to the ninth to twelfth through vias 2409 to 2412 in the first horizontal direction DR1.

Each of the first to sixteenth through vias 2401 to 2416 may be arranged on each of the landing pads 150. Each of the first to sixteenth through vias 2401 to 2416 may be electrically connected to each of the word line contact 130 and the word line pad portion WLP through each of the landing pads 150, the first wirings 144, and the first vias 142.

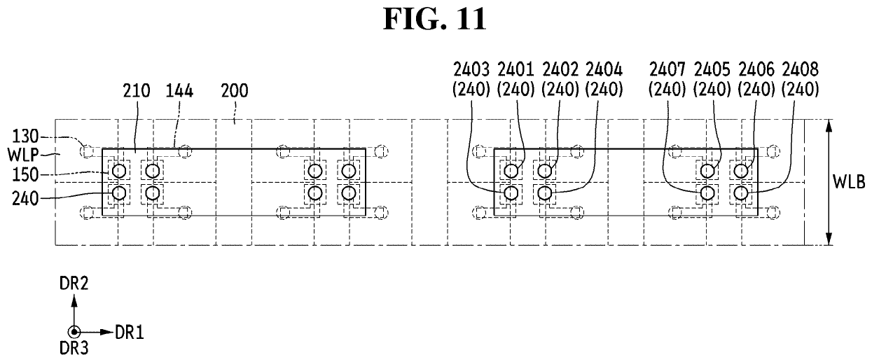

FIG. 11 is an exemplary layout view illustrating a word line connection region of a semiconductor memory device according to some embodiments. For convenience of description, redundant portions of those described with reference to FIGS. 1 to 10 will be briefly described or omitted.

Referring to FIG. 11, in the semiconductor memory device according to some embodiments, each via group 40 may include first to eighth through vias 2401 to 2408 spaced apart from one another by 2*4. The first to eighth through vias 2401 to 2408 may pass through one insulating pattern 210.

The via group 40 may include through vias 240 spaced apart from one another in various ways. For example, the via group 40 may include first to eighth through vias 2401 to 2408 spaced apart from one another by 4*2. For another example, the insulating pattern 210 may be formed for each through via 240. That is, one through via 240 may pass through one insulating pattern 210.

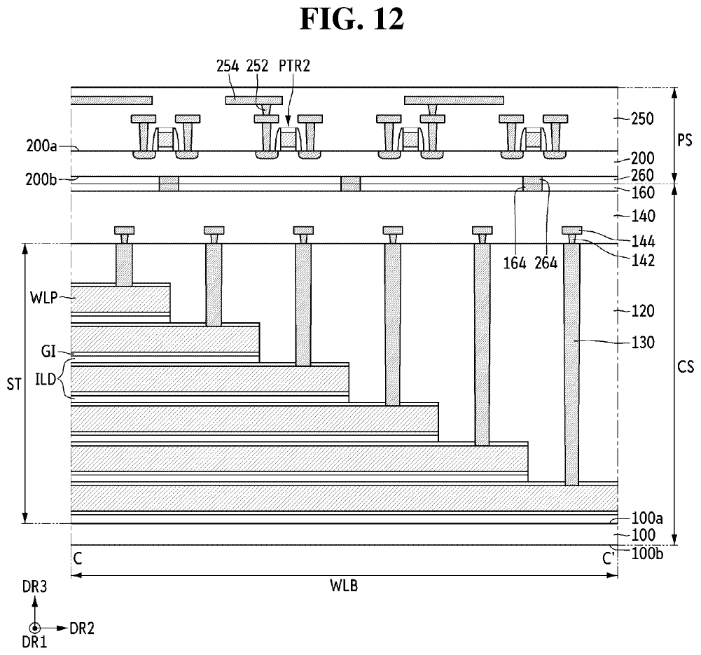

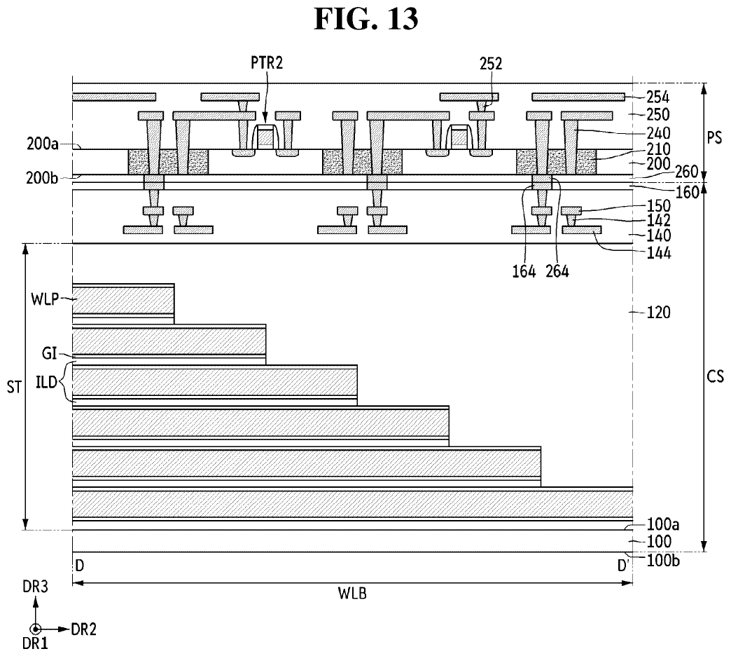

FIGS. 12 and 13 are cross-sectional views illustrating a semiconductor memory device according to some embodiments. FIG. 12 is a cross-sectional view taken along line C-C′ of FIG. 3. FIG. 13 is a cross-sectional view taken along line D-D′ of FIG. 3. For convenience of description, redundant portions of those described with reference to FIGS. 1 to 7 will be briefly described or omitted.

Referring to FIGS. 12 and 13, the semiconductor memory device according to some embodiments may have a chip-to-chip (C2C) structure bonded by a wafer bonding method. After the cell structure CS and the peripheral circuit structure PS are manufactured, the semiconductor memory device may be manufactured by bonding the cell structure CS to the peripheral circuit structure PS.

The cell structure CS may further include a first bonding pad 164 in the first bonding insulating layer 160. The first bonding pad 164 may be electrically connected to the first vias 142, the first wirings 144, the landing pad 150, and the word line contacts 130. For example, each of the first bonding pads 164 may be formed on each landing pad 150, and may be electrically connected to each landing pad 150. The first bonding pad 164 may be arranged on the uppermost metal layer based on the first surface 100a of the first substrate 100.

The peripheral circuit structure PS may further include a second bonding pad 264 in the second bonding insulating layer 260. The second bonding pad 264 may be electrically connected to the second vias 252, the second wirings 254, and the through vias 240. For example, each second bonding pad 264 may be electrically connected to each through via 240. For example, each second bonding pad 264 may be in contact with each through via 240. The second bonding pad 264 may be arranged on the lowermost metal layer based on the third surface 200a of the second substrate 200.

The first bonding pad 164 of the cell structure CS and the second bonding pad 264 of the peripheral circuit structure PS may be connected to one another. The first bonding pad 164 and the second bonding pad 264 may be in contact with one another. The first bonding insulating layer 160 and the second bonding insulating layer 260 may be in contact with one another.

The second peripheral circuit transistors PTR2 may be electrically connected to the pad portion WLP of the word line WL through the second vias 252 and the second wirings 254, the through vias 240, the second bonding pads 264, the first bonding pads 164, the landing pads 150, the first vias 142 and the first wirings 144, and the word line contacts 130.

In embodiments, there is provided a method for manufacturing a semiconductor memory device comprising: providing a cell structure; and providing a peripheral circuit structure on the cell structure, wherein: the cell structure includes a first substrate, stack structures spaced apart from one another in a first horizontal direction on the substrate, including word lines spaced apart from one another in a vertical direction, each word line having a stepwise shape, word line contacts electrically connected to the word lines, and landing pads electrically connected to the word line contacts, the peripheral circuit structure includes a second substrate, insulating patterns passing through the second substrate, and through vias electrically connected to the landing pads, each of the through vias constitutes via groups including first to fourth through vias adjacent to one another, and the first to fourth through vias of the via groups pass through the insulating patterns.

Although the embodiments of the present disclosure have been described with reference to the accompanying drawings, it will be apparent to those skilled in the art that the present disclosure may be fabricated in various forms without being limited to the above-described embodiments and may be embodied in other specific forms without departing from technical spirits and essential characteristics of the present disclosure. Thus, the above embodiments are to be considered in all respects as illustrative and not restrictive.

What is claimed is:

1. A semiconductor memory device comprising:
a cell structure; and
a peripheral circuit structure on the cell structure,
wherein:
the cell structure includes a first substrate, stack structures spaced apart from one another in a first horizontal direction on the substrate, including word lines spaced apart from one another in a vertical direction, each word line having a stepwise shape, word line contacts electrically connected to the word lines, and landing pads electrically connected to the word line contacts,
the peripheral circuit structure includes a second substrate, insulating patterns passing through the second substrate, and through vias electrically connected to the landing pads,
each of the through vias constitutes via groups including first to fourth through vias adjacent to one another, and
the first to fourth through vias of the via groups pass through the insulating patterns.

2. The semiconductor memory device of claim 1, wherein the first through via is adjacent to the third through via in a second horizontal direction,
the second through via is adjacent to the first through via in the first horizontal direction, and is adjacent to the fourth through via in the second horizontal direction, and
the fourth through via is adjacent to the third through via in the first horizontal direction.

3. The semiconductor memory device of claim 2, wherein the landing pads include first to fourth landing pads,
each of the landing pads is electrically connected to each of the first to fourth through vias,
the via groups include a first via group and a second via group adjacent to the first via group in the first horizontal direction, and
a distance between the first landing pad of the first via group and the second landing pad of the first via group is less than a distance between the second landing pad of the first via group and the first landing pad of the second via group.

4. The semiconductor memory device of claim 2, wherein the landing pads include first to fourth landing pads,
each of the landing pads is electrically connected to each of the first to fourth through vias,
the via groups include a first via group and a second via group,
the second via group is adjacent to the first via group in the second horizontal direction, and
a distance between the first landing pad of the second via group and the third landing pad of the second via group is less than a distance between the third landing pad of the second via group and the first landing pad of the first via group.

5. The semiconductor memory device of claim 1, wherein the insulating patterns are arranged in zigzags along a second horizontal direction.

6. The semiconductor memory device of claim 1, wherein the insulating patterns are spaced apart from one another in the first horizontal direction and a second horizontal direction.

7. The semiconductor memory device of claim 1, wherein each of the landing pads is in contact with each of the through vias.

8. The semiconductor memory device of claim 1, wherein the cell structure further includes a first bonding pad electrically connected to the word line contacts,
the peripheral circuit structure further includes a second bonding pad electrically connected to the through vias, and
the first bonding pad and the second bonding pad are in contact with one another.

9. The semiconductor memory device of claim 1, wherein a portion of each of the through vias overlaps the word line, which is electrically connected to each of the through vias, in the vertical direction.

10. The semiconductor memory device of claim 1, wherein the landing pads include first to fourth landing pads electrically connected to the first to fourth through vias, respectively, and
each of the insulating patterns overlaps the first to fourth landing pads in the vertical direction.

11. The semiconductor memory device of claim 1, wherein each of the via groups further includes fifth to eighth through vias, which are adjacent to one another, among the through vias, and
the fifth to eighth through vias are adjacent to the first to fourth through vias in the first horizontal direction or the second horizontal direction.

12. The semiconductor memory device of claim 1, wherein the via groups further includes fifth to eighth through vias adjacent to one another, ninth to twelfth vias adjacent to one another, and thirteenth to sixteenth vias adjacent to one another,
the first to fourth through vias are adjacent to the ninth to twelfth through vias in a second horizontal direction,
the fifth to eighth through vias are adjacent to the first to fourth through vias in the first horizontal direction, and are adjacent to the thirteenth to sixteenth through vias in the second horizontal direction, and
the thirteenth to sixteenth through vias are adjacent to the ninth to twelfth through vias in the first horizontal direction.

13. The semiconductor memory device of claim 1, wherein the peripheral circuit structure further includes peripheral circuit transistors electrically connected to the through vias on the second substrate.

14. A semiconductor memory device comprising:
a cell structure; and
a peripheral circuit structure on the cell structure,
wherein:
the cell structure includes a first substrate, stack structures spaced apart from one another in a first horizontal direction on the substrate, including word lines spaced apart from one another in a vertical direction, each word line having a stepwise shape, word line contacts electrically connected to the word lines, and landing pads electrically connected to the word line contacts,
the peripheral circuit structure includes a second substrate, insulating patterns passing through the second substrate, through vias electrically connected to the landing pads in the insulating patterns, and peripheral circuit transistors electrically connected to the through vias on the second substrate, and
the insulating patterns are spaced apart from one another in the first horizontal direction and a second horizontal direction.

15. The semiconductor memory device of claim 14, wherein a portion of each of the landing pads overlaps each of the word lines in the vertical direction.

16. The semiconductor memory device of claim 14, wherein the insulating patterns are arranged in zigzags along the second horizontal direction.

17. The semiconductor memory device of claim 14, wherein the landing pads include first to fourth landing pads,
the through vias include first to fourth through vias electrically connected to the first to fourth landing pads, respectively, and
the first to fourth through vias pass through the insulating patterns, respectively.

18. A semiconductor memory device comprising:
a cell structure and a peripheral circuit structure, which include a bit line connection region and a word line connection region,
wherein:
the cell structure includes a first substrate, stack structures spaced apart from one another in a first horizontal direction on the first substrate, and word line contacts,
each of the stack structures includes a bit line extended from the bit line connection region in a vertical direction, semiconductor patterns connected to the bit line in the bit line connection region, extended in the first horizontal direction and spaced apart from one another in the vertical direction, data storage elements connected to the semiconductor patterns in the bit line connection region, word lines including pad portions extended in a second horizontal direction from the bit line connection region to the word line connection region, crossing the semiconductor patterns in the bit line connection region and having a stepwise shape in the word line connection region, and word line contacts on pad portions,
the peripheral circuit structure includes a second substrate, insulating patterns passing through the second substrate in the bit line connection region, through vias passing through the insulating patterns, and peripheral circuit transistors on the second substrate in the bit line connection region,
each of the through vias constitutes via groups including first to fourth through vias adjacent to one another, and
the first to fourth through vias of each of the via groups pass through the insulating patterns, respectively.

19. The semiconductor memory device of claim 18, wherein the first substrate includes a first surface on which the stack structures are arranged,
the second substrate includes a second surface on which the peripheral circuit transistors are arranged, and a third surface opposite to the second surface, and
the first surface is opposite to the third surface.

20. The semiconductor memory device of claim 18, wherein the insulating patterns are spaced apart from one another in the first horizontal direction and the second horizontal direction.
